(19) United States
(12) Patent Application Publication
(10) Pub. No.: US 2019/0182965 A1
(43) Pub. Date: Jun. 13, 2019

(54) System and Method for Applying Potting Material to a Printed Circuit Board

(71) Applicant: Celestica International LP, Toronto (CA)

(72) Inventors: Xia E. ZHANG, Oakville (CA); Ji Fang QI, Shen Zhen City (CN); David John LEKX, Toronto (CA); Jeff EIGNER, Longmont, CO (US)

(21) Appl. No.: 16/195,565

(22) Filed: Nov. 19, 2018

Related U.S. Application Data
(63) Continuation of application No. PCT/CA2017/050589, filed on May 16, 2017.
(60) Provisional application No. 62/337,671, filed on May 17, 2016.

(51) Int. Cl. H05K 3/28; H05K 1/18

(52) U.S. Cl. CPC H05K 3/284; H05K 1/186; H05K 2203/1316; H05K 2203/0169; H05K 2201/2018

(57) ABSTRACT

A frame is provided, for applying potting material to a printed circuit board (PCB). The frame includes a plurality of substantially vertically oriented walls arranged to isolate a surface of the PCB into a plurality of zones. This allows the frame to be aligned over the surface of the PCB to isolate the surface of the PCB into a plurality of zones, each zone comprising at least one PCB component; and allows the potting material to be applied into the zones to achieve coverage of the PCB components in that zone.

### CROSS-REFERENCE TO RELATED APPLICATION(S)

This application is a continuation of PCT Application No. PCT/CA2017/050589 filed on May 16, 2017, which claims priority from U.S. Provisional Patent Application No. 62/337,671 filed on May 17, 2016, both incorporated herein by reference.

### TECHNICAL FIELD

The following relates to systems and methods for applying potting material to a printed circuit board (PCB).

### DESCRIPTION OF THE RELATED ART

In electronics assembly and manufacturing, potting is a process of applying a solid or gelatinous compound to a completed electronic assembly. Potting may be performed in order to provide resistance to shock and vibration, or for preventing the ingress of moisture and/or other so called contaminants, such as corrosive agents, or for thermal performance reasons. For example, it is currently required that photovoltaic solar electronic assemblies (e.g., micro inverters and rapid shut down devices) have the printed circuit board (PCB) assembly protected by at least a 1/32 inch (0.79 mm) thick layer of material applied through, for example potting, in order to achieve a pollution degree of 1 per section 25.4(f) of the UL1741 standard. This standard specifies appropriate distances between high voltage and safety low voltage signals, to ensure operator safety, and are dependent on environmental conditions (i.e. the pollution degree). The higher the pollution degree, the smaller the distance that is required between components. There are typically other government or regulatory requirements, for example, that the protective layer is achieved without having air bubbles in the potting material. These requirements may also apply to devices that are included in a junction box of a solar panel and in many other electronics applications.

The components on or embedded in a PCB often have different heights relative to the surface(s) of the PCB, and the potting material is in a fluid state during the manufacturing process. As such, to ensure the full coverage of potting material on the components, the potting material is applied such that it fills enough (or the entirety) of the container in order to provide the requisite layer over and above the highest components, as shown in FIGS. 1(a) and 1(b). This can, in many cases, result in the application of excessive and redundant or wasteful potting material. Since the UL1741 specification requires the components to be covered with a minimum thickness of 1/32 inch (0.79 mm), when the highest components are appropriately covered, the lower components would likely be over coated. This is also the case with PCBs that are mounted with a gap under the PCB and above the floor of the enclosure as shown in FIGS. 1(c) and 1(d).

One solution to the problem illustrated in FIGS. 1(a) and 1(b), is to apply a plastic separator or cover over the PCB assembly, as shown in FIG. 2. The plastic separator is used to adjust the fluid volume application to components of different heights by physical separation of space. In this way, the space underneath the plastic separator is to be potted, and the areas above the plastic separator would not be potted. Such a plastic separator is meant to restrain the potting material in the dedicated areas, and prevent it from over flow to the other space above the structure. However, a problem encountered with this approach is that the viscosity of the potting material can prevent it from flowing sufficiently underneath the separator, resulting in voids around the components which are further away from injection gates in the structure. As a result, the separator may require multiple inlets and vents, adding to the complexity of the structure in order to achieve a consistently sufficient layer of potting material. Moreover, because the separator is generally horizontally oriented, the application of the potting material is not visible during the manufacturing process, and thus it can be difficult to verify the effectiveness of the inlets and vents. Therefore, in some case, in order to ensure adequate potting material coverage requires section cuts in the separator and prohibitive delays resulting from design adjustment. These issues can also arise if the plastic separator was used with a PCB assembly as illustrated in FIGS. 1(c) and 1(d).

It is an object of the following to address at least one of the above-noted drawbacks.

### SUMMARY

The following provides systems and methods to reduce the amount of potting material used in electronics assemblies.

In one aspect, there is provided a frame for applying potting material to a printed circuit board (PCB), the frame comprising a plurality of substantially vertically oriented walls arranged to isolate a surface of the PCB into a plurality of zones.

In this way, pottant can be applied to areas having differing component heights throughout the board. These walls enable pottant to be applied simultaneously or consecutively to the separate regions, in differing volumes, to achieve sufficient coverage, while minimizing excess potting material, particularly over lower profile components.

In another aspect, there is provided a method of applying potting material to a printed circuit board (PCB), the method comprising: aligning a frame over a surface of the PCB, the surface comprising a plurality of components having different heights, the frame comprising a plurality of substantially vertically oriented walls arranged to isolate the surface of the PCB into a plurality of zones, each zone comprising at least one PCB component; and applying the potting material into a plurality of the zones to achieve coverage of the PCB components in that zone, wherein at least two zones have potting material levels that are different.

In yet another aspect, there is provided a device for applying potting material to a printed circuit board (PCB), the device comprising a removable frame having a contour that substantially follows contours defined by components of the PCB to enable a gap to be defined between the contour and the PCB components to enable the potting material to be injected into the gap to generate a layer of potting material over the PCB components after removing the frame from the cured potting material.

### BRIEF DESCRIPTION OF THE DRAWINGS

Embodiments will now be described by way of example only with reference to the appended drawings wherein:

FIG. 1(a) is a cross-sectional view of a printed circuit board (PCB) housed in an enclosure;

FIG. 1(b) is a cross-sectional view of the PCB and enclosure shown in FIG. 1(a) with potting material added according to a prior art technique;

FIG. 1(c) is a cross-sectional view of a PCB housed in an enclosure with a gap between the underside of the PCB and a floor of the enclosure;

FIG. 1(d) is a cross-sectional view of the PCB and enclosure shown in FIG. 1(c) with potting material added according to a prior art technique;

FIG. 2 is a cross-sectional view of the PCB and enclosure shown in FIG. 1(a) with potting material adding according to another prior art technique;

FIG. 3 is a perspective view of a frame for separating a PCB housed in an enclosure, into zones of differing heights to facilitate the application of potting material;

FIG. 4 is a perspective view of a frame for separate a PCB into zones of different heights to facilitate the application of potting material, wherein the PCB is not housed in an enclosure;

FIG. 5A is a cross-sectional view of a PCB housed in an enclosure, with a frame for separating the PCB into multiple zones;

FIG. 5B. is a cross-sectional view of the PCB and enclosure shown in FIG. 5A after potting material has been applied;

FIG. 5C is a cross-sectional view of a PCB housed in an enclosure with a gap between the underside of the PCB and a floor of the enclosure, with a frame for separating the PCB into multiple zones;

FIG. 5D is a cross-sectional view of the PCB and enclosure shown in FIG. 5C after potting material has been applied;

FIG. 6A is a cross-sectional view of a PCB housed in an enclosure, with a frame similar to that shown in FIG. 5A but with walls that do not extend fully to the PCB surface;

FIG. 6B is a cross-sectional view of the PCB and enclosure shown in FIG. 6A after potting material has been applied;

FIG. 6C is a cross-sectional view of the PCB and enclosure shown in FIG. 6A after potting material has been applied and the frame removed;

FIG. 7 is a cross-sectional view of a PCB without an enclosure with a frame for separate the PCB into multiple zones, after the potting material has been applied;

FIG. 8 is a cross-sectional view of a removable jig for controlling the application of potting material to a PCB according to differing component heights;

FIG. 9 is a cross-sectional view of the jig shown in FIG. 8 inserted in an enclosure;

FIG. 10 is a cross-sectional view of the jig shown in FIGS. 8 and 9 after application of potting material and during removal of the jig; and

FIG. 11 is a flow chart illustrating steps that may be performed in using a frame for applying potting material to a PCB.

### DETAILED DESCRIPTION

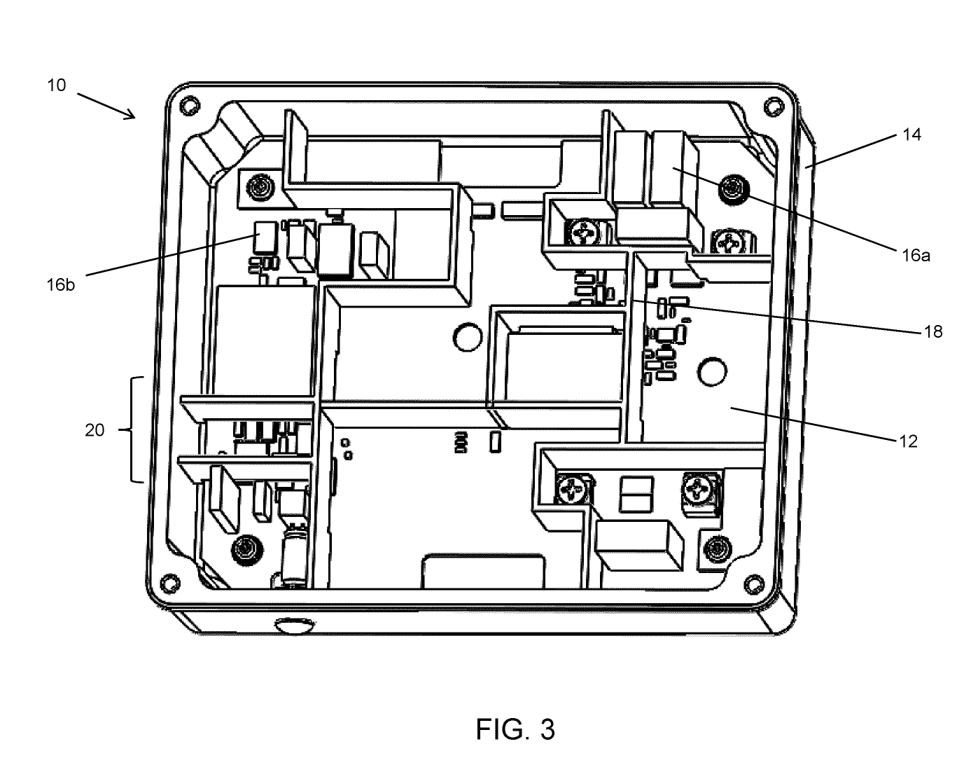

Turning now to the figures, FIG. 3 illustrates an electronics assembly 10 that includes a PCB 12 housed in, or otherwise supported by or contained within, an enclosure 14. The PCB 12 includes a number of components 16, including surface mount and/or embedded components 16, that protrude or extend from one or more surfaces of the PCB 12. In the example shown in FIG. 3, both relatively high profile components 16a are present, as well as relatively low profile components 16b. To enable potting material to be applied to different areas, without having to use excessive potting material in order to ensure the highest component(s) are covered, a frame 18 is inserted into the enclosure 14, to create a number of regions or zones 20. In this way, whether the potting material is applied concurrently, or sequentially, the volume of potting material applied in each zone is only as much as needed to cover the components 16 in that zone 20.

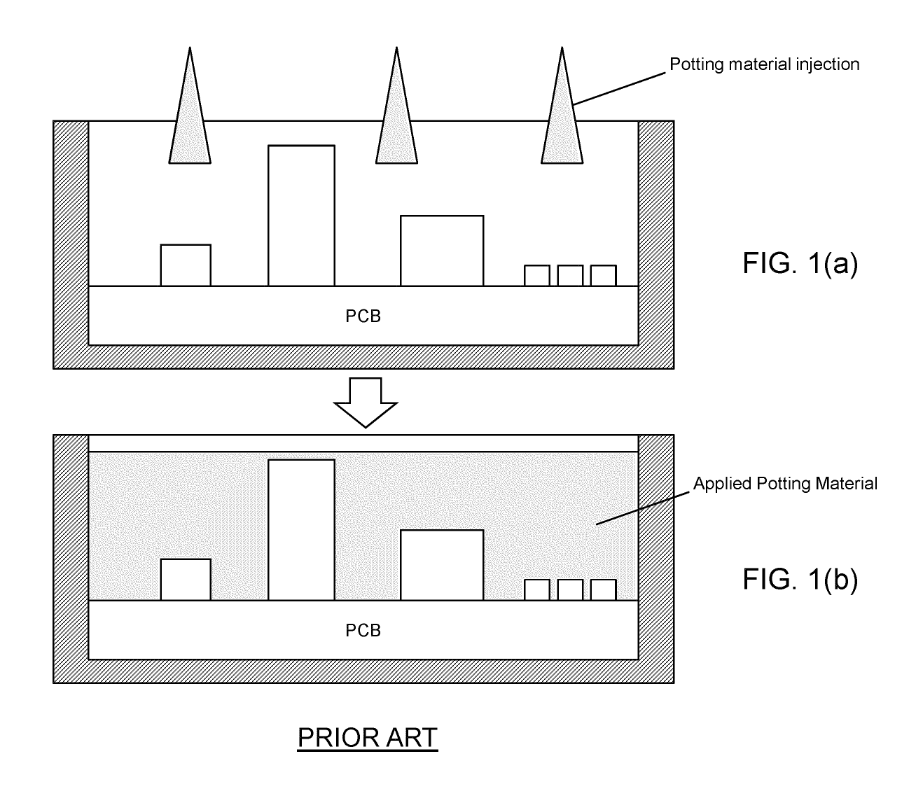

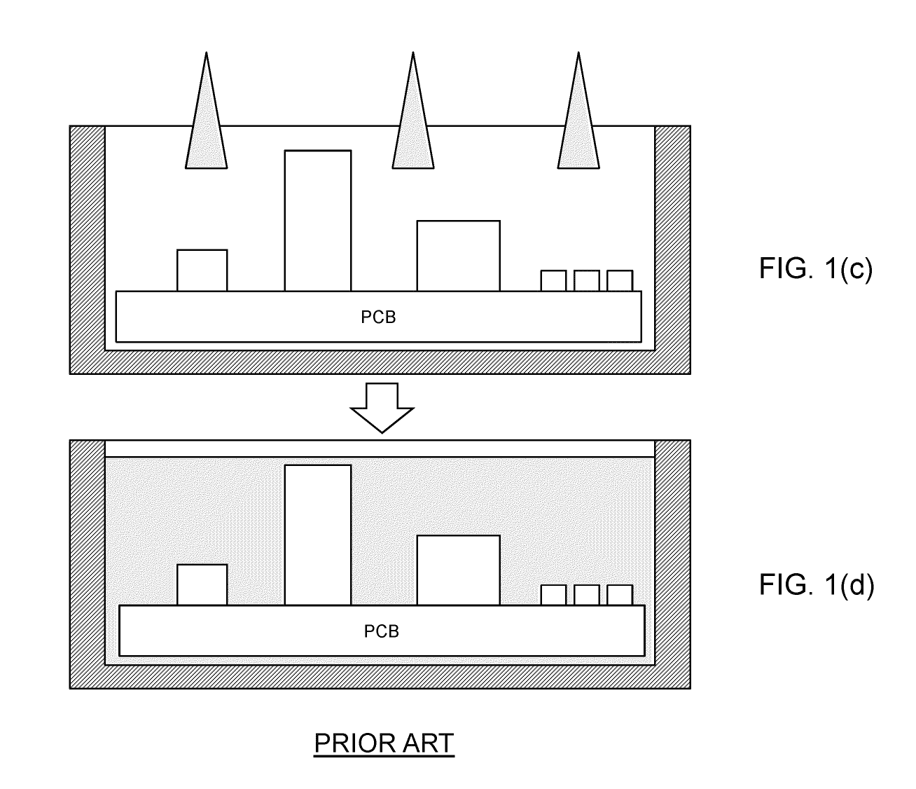

In the embodiment shown in FIG. 3, the frame 18 is designed to be constructed of any suitable material, such as various plastics, and includes a series of separation walls to isolate zones 20 having components 16 with different heights, thereby dividing the components 16 into separate “vessels”, without potting material fluid connections therebetween. Therefore, for the zones 20 with lower profile components 16b, less volume of the potting material can be applied (than would occur without the frame 18—e.g., per FIG. 1(b)), and for areas with higher profile components 16a, a sufficient quantity of the potting material can be applied to cover those higher components 16a. This would typically result in a higher fluid level in that zone 20, however, not necessarily a higher volume of pottant, since the components 16 being potted may themselves have higher volumes.

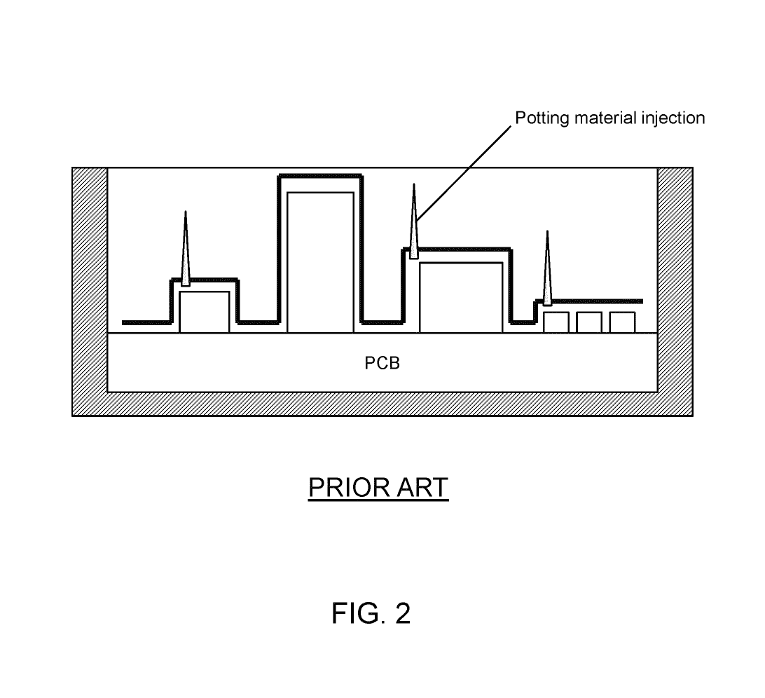

Since the dividing walls of the frame 18 restrain the potting material from flowing between the different vessels, both high and low profile components 16 would be able to be applied with an appropriate volume of potting material, such that both “void space” and over-coating problems can be prevented. Moreover, it can be appreciated that since the walls of the frame 18 are vertically (or substantially vertically) oriented, an improved amount of visibility for problem checking is provided when compared to, for example, the prior art implementation shown in FIG. 2. For example, cutting or dissection can be prevented, in order for potting material checks to be made, to ensure that the potting material level reaches the requisite targets.

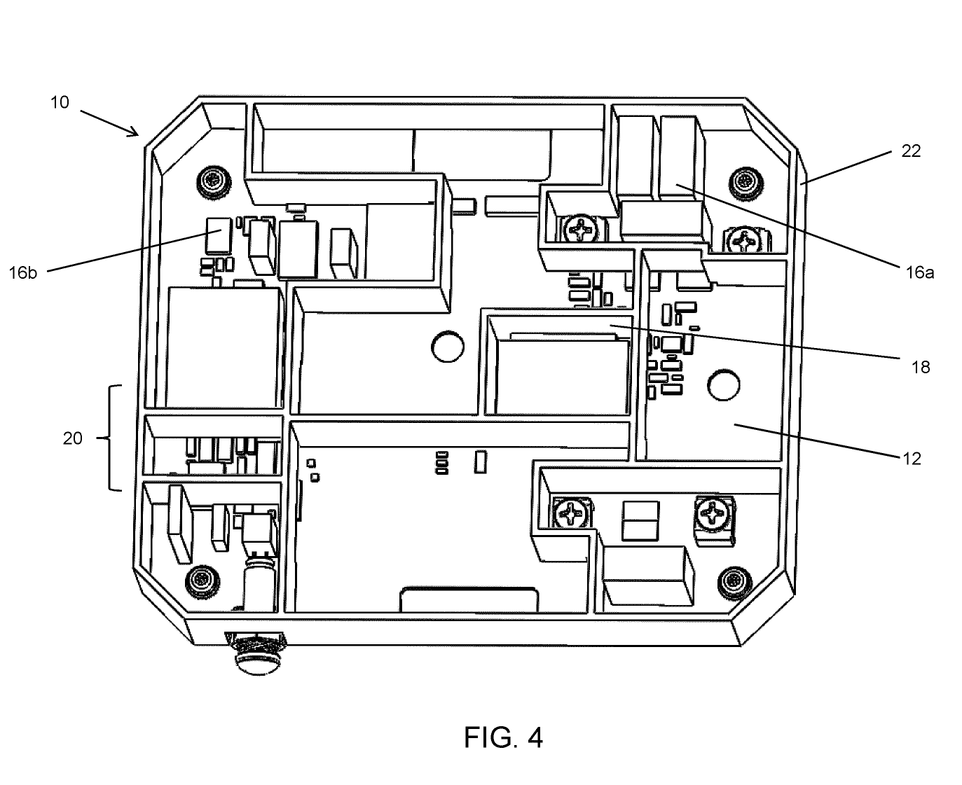

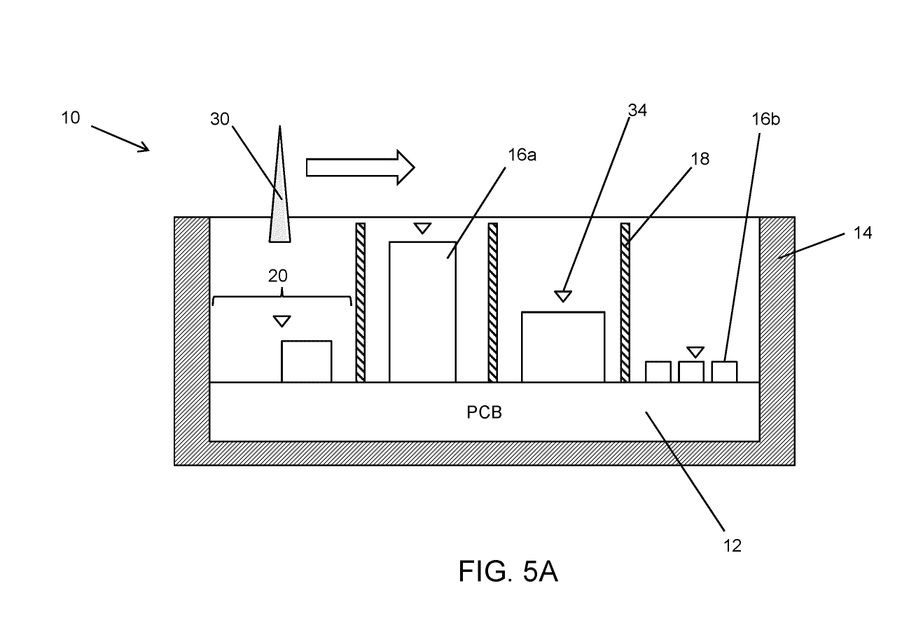

In the embodiment shown in FIG. 3, the frame 18 is sized to fit within an enclosure 14 in order to create the zones 20. However, as shown in FIG. 4, for PCBs 12 that need to be potted, but are not in an enclosure, the frame 18 can be adapted to include a peripheral wall 22 to effectively contain potting material within the zones 20 that are adjacent the edges of the PCB 12. As such, it can be appreciated that the frame 18 can be configured to suit any electronics assembly 10 in order to isolate the zones 20 as herein described.

Depending on the material used to construct the frame 18, the frame 18 is typically inserted and kept in the enclosure 14 (see FIG. 3) or as part of the PCB 12 (see FIG. 4) and becomes fixed after the potting material is cured. The frame 18 can have walls that are of the same height (as illustrated in FIGS. 3 and 4), or having different heights, e.g., to generally correspond to the heights of the components in different zones 20.

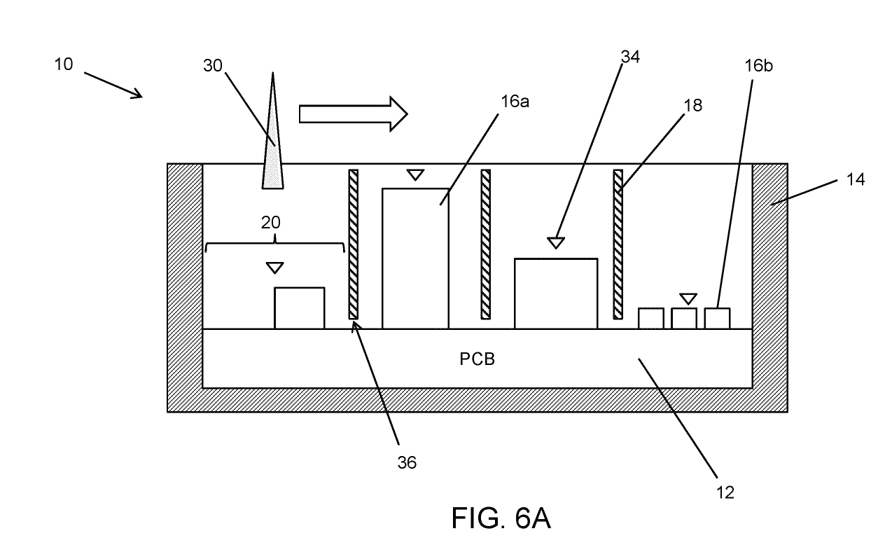

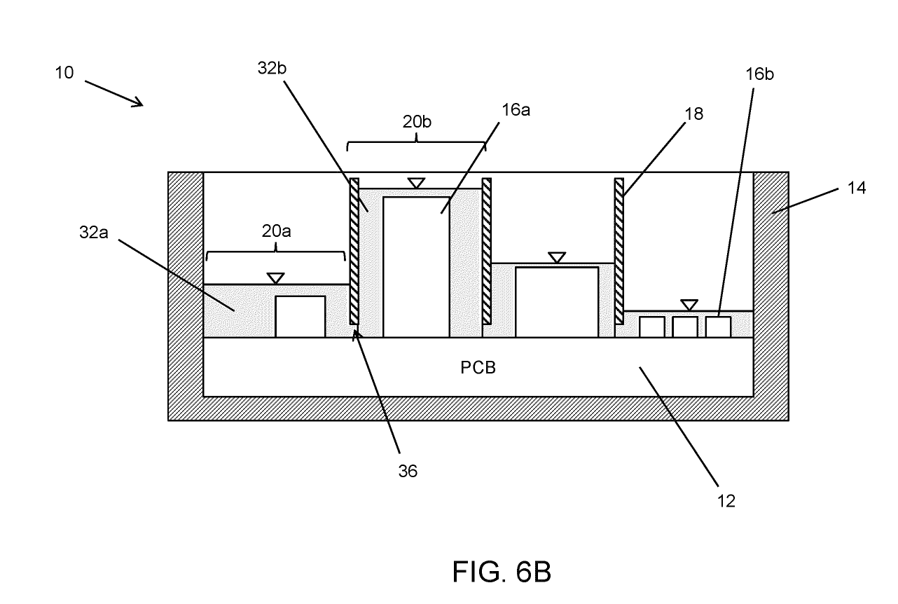

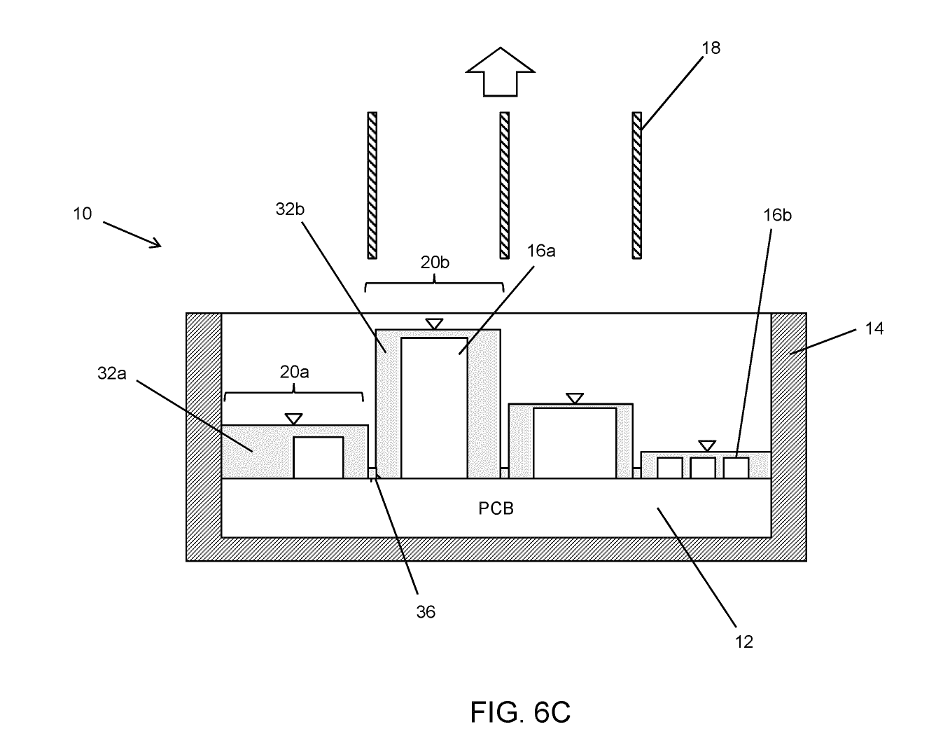

However, it can be appreciated that with appropriate materials that enable the frame 18 to be separated from the potting material, the frame 18 can be removed post-curing with the above-noted effect in place. For such an implementation, which is shown in FIG. 6 and described below, a gap (e.g., of approximately 1 mm) can be established between the bottom of the frame 18 and the surface of the PCB 12, with the frame 18 being supported above the PCB surface using any suitable method such as attachment to the enclosure 14, a spandrel, jig, or other supporting structure. The potting material 30 would fill into this gap, and because of the viscosity of the potting material 30, this can be done with a limited amount of flow through the gap(s). It can be appreciated that such a removable frame 18 can include all zones 20, or smaller individual frames (not shown) can be applied successively for each zone 20, and removed after that zone 20 has cured. Moreover, the frame 18 can be constructed, e.g. with walls of different heights, such that the frame 18 is not visible after the potting material 30 has been applied since the framed element is at a different height than the pottant trace or unframed portion.

The frame 18 can be constructed from a plastic as mentioned above, or from one or more various other materials, such as composite materials, paper, cardboard, etc.; or any other material that is found to be economical to leave behind after applying the potting material, or can be removed from the potting material post-curing. Also, the frame 18 can be constructed as a single unit, or can be assembled from multiple frame pieces (not shown).

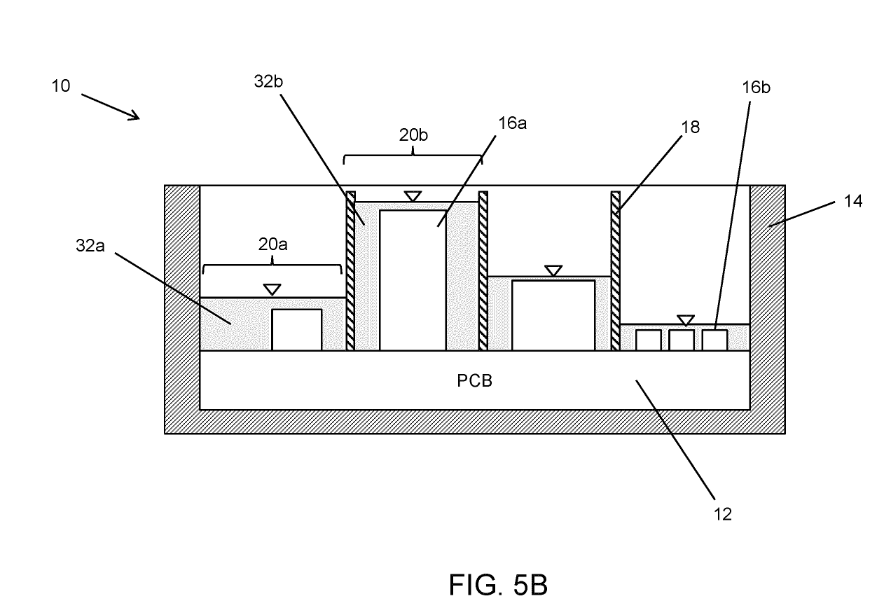

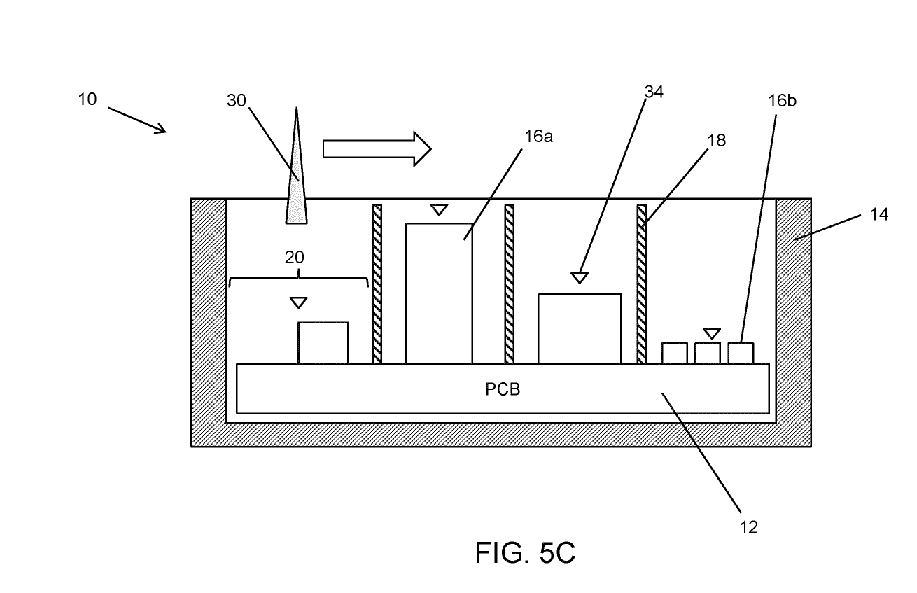

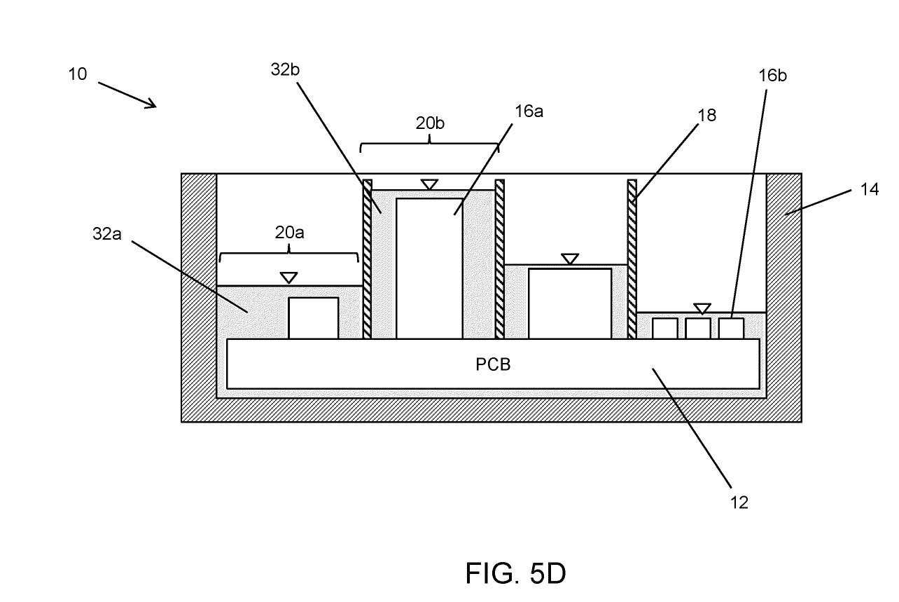

FIG. 5A provides a schematic cross-sectional view of an example of a PCB 12 having both higher profile components 16a and lower profile components 16b, wherein the PCB 12 is supported or contained within an enclosure 14. In this example, the frame 18 separates the PCB's surface area into four zones, and each zone includes a fill marker 34 that can be applied to a wall of the frame 18 or the enclosure 14 in order to indicate to an operator (or machine vision/detection function), to what level the potting material 30 should be filled. The potting material 30 can be applied as shown in FIG. 5A, on a zone-by-zone sequential basis, or multiple material sources/sprayers/applicators can be used simultaneously.

As shown in FIG. 5B, after application of the potting material 30, each zone 20 includes sufficient coverage of cured potting material 32, but at different levels. For example, the cured potting material 32a in a first zone 20a has a lower level than the cured potting material 32b in an adjacent zone 20b, but with similar overall volumes applied and excessive potting material coverage minimized. In this example, the frame 18 is left behind as part of the potted PCB 12 and enclosure 14. It can be appreciated that the walls of the frames 18 could have different heights or portions thereof removed to minimize frame portions extending above the potted portions.

FIGS. 5C and 5D illustrate the same technique and structure as shown in FIGS. 5A and 5B, but for a PCB 12 that is mounted in the enclosure 14 such that there is a gap between the underside of the PCB and the floor of the enclosure 14 into which potting material is filled. FIGS. 5C and 5D also show potting material being filled around the side edges of the PCB, which may also be applicable in the scenario shown in FIGS. 5A and 5B. It can be appreciated that the applicability of the principles discussed herein to both PCB mounting configurations (i.e. directly to the enclosure 14 or slightly above the enclosure) is similar for all embodiments shown herein, and duplicate illustrations are omitted only for the sake of brevity and in view of the variations shown in FIGS. 5C and 5D.

FIGS. 6A to 6B illustrate another implementation wherein the frame 18 is supported above the PCB 12, with a gap 36 established therebetween as illustrated in FIG. 6B. As illustrated in FIG. 6B, the applied potting material 32 can flow under the frame 18 to ensure complete coverage of the PCB 12, while additionally achieving different heights of potting material in different zones 20. It can be appreciated that the application of potting material 30 in this example can be done in a continuous or sequential process in which a first layer is applied to achieve a minimum layer to ensure coverage of the PCB 12, and one or more additional layers that achieve the differing heights within the zones 20, with the frame 18 being inserted either at the beginning or after application of the first, baseline layer. As such, it can be appreciated that various steps can be used in different order. FIG. 6C illustrates the removal of the frame 18 and the desired coverage of the PCB 12.

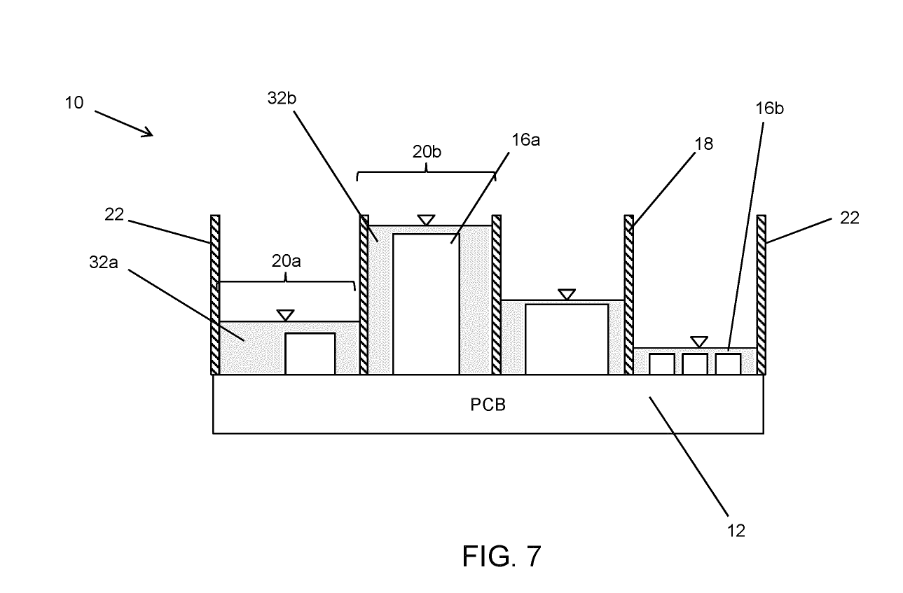

FIG. 7 illustrates the same effect as in FIG. 6, but with a frame 18 that includes an outer or peripheral wall 22. That is, the peripheral wall 22 is included to provide the same functionality as the enclosure 14 in that the individual vessels are created, without potting material flow therebetween.

As noted above, it can be appreciated that while the walls of the frames 18 shown in FIGS. 3 to 7 are uniform in height, such walls can have different heights, for example, according to the heights of the components 16 within a particular zone 20.

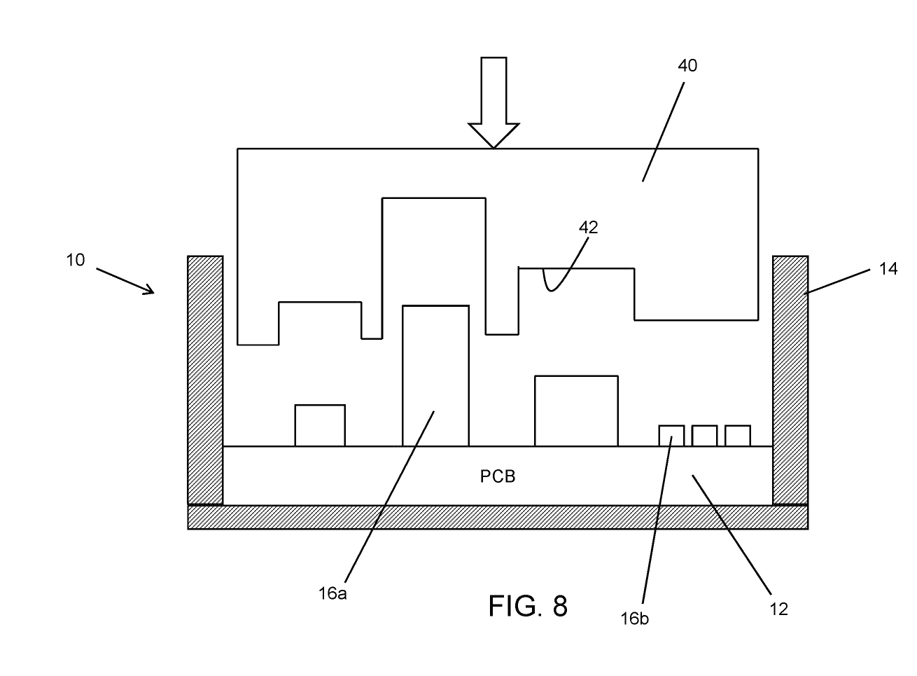

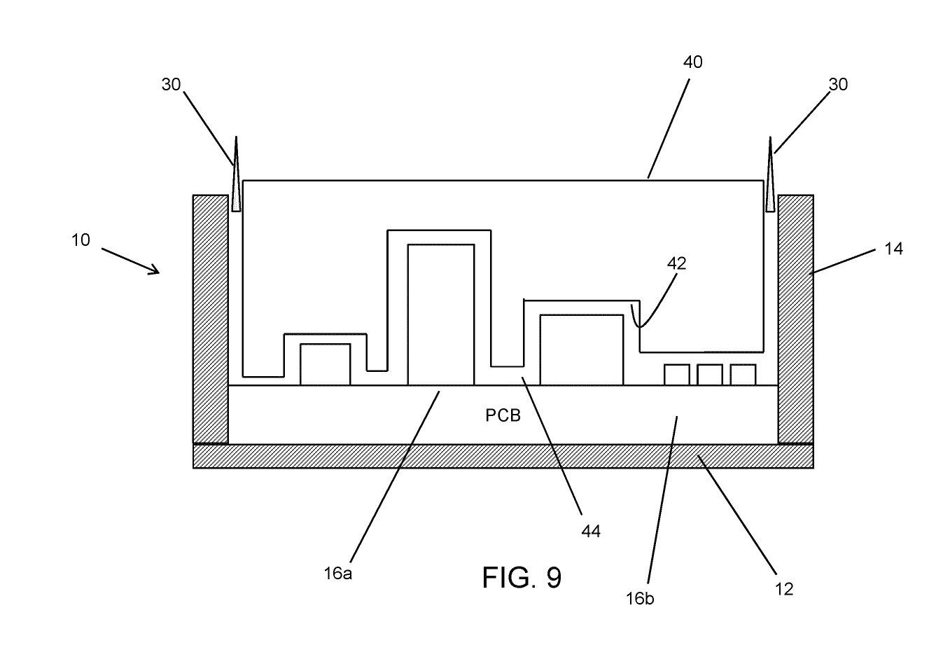

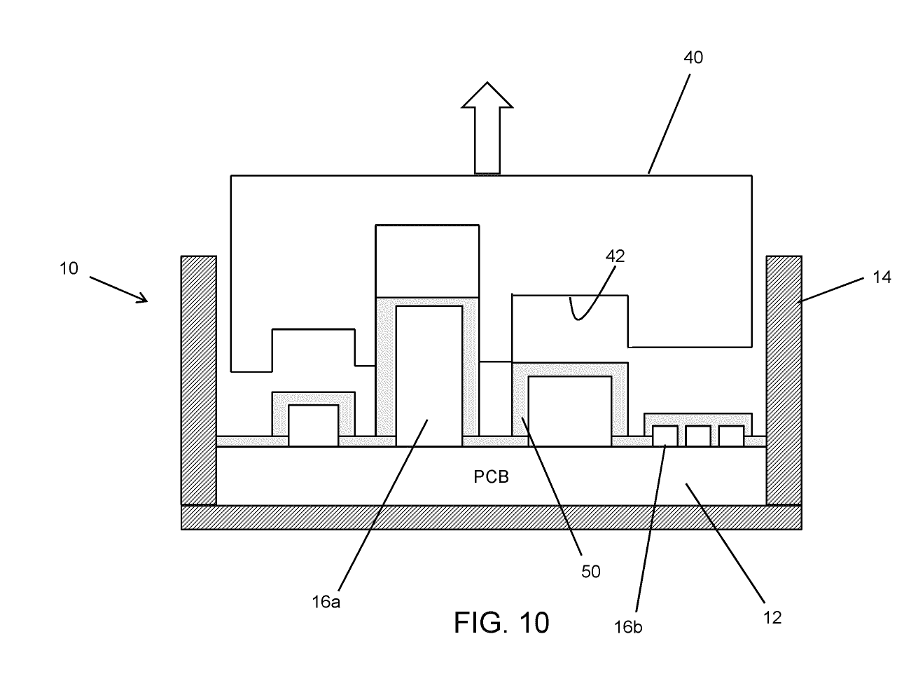

As illustrated in FIGS. 8 to 10, when a suitable potting material 30 and frame material are chosen, such that the frame 18 can be separated from the potting material 30 post-curing, a removable contoured frame, hereinafter referred to as a “jig” 40 could instead be constructed, which has a PCB-facing profile 42 that follows the profile of the components 16 of the PCB 12, including both higher components 16a and lower components 16b. FIG. 8 illustrates the jig 40 which is lowered towards the PCB 12 such that it is held in place with a sufficient gap 44 between the profile 42 and the PCB components 16 as illustrated in FIG. 9. A potting material 30 of a suitable viscosity to enable it to flow through the gap 44 in a consistent manner, is applied at either or both ends of the jig 40, but may also be applied using any suitable number of injection openings in the jig 40 (not shown). As shown in FIG. 10, in this way, after the potting material 30 has cured, and the jig 40 has been removed, a suitable layer 50 of potting material 30 is achieved.

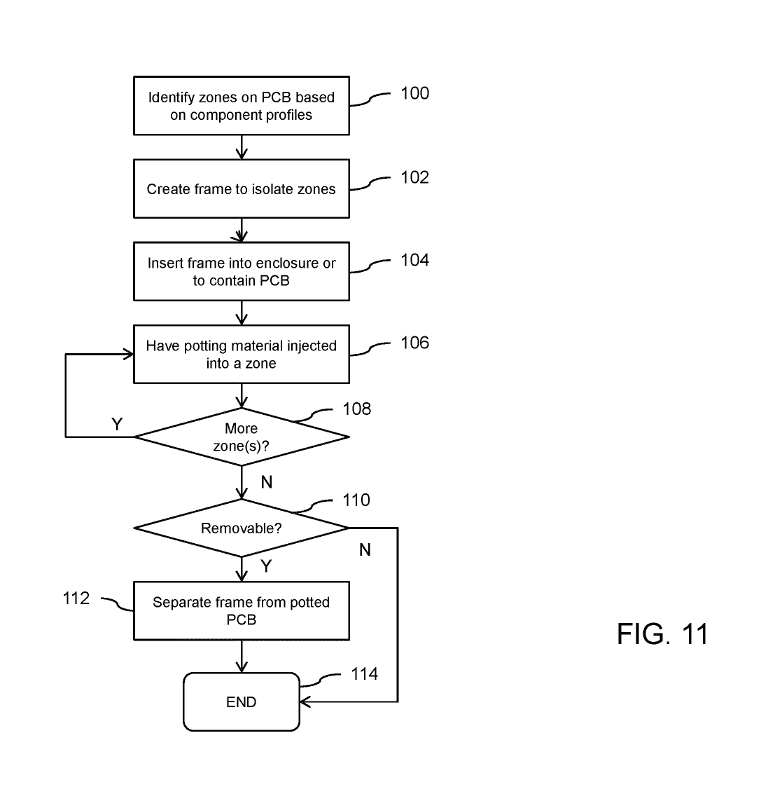

Turning now to FIG. 11, an example of a method for applying potting material 30 to a PCB 12 is shown. At step 100, a plurality of zones 20 on the PCB 12 to which potting material 30 is to be applied are identified, based on the profiles of the components 16 that are protruding from the surface of the PCB 12. It can be appreciated that the layout of the PCB 12 can also be designed with the potting frame 18 in mind, such that relatively higher components 16a are grouped together, to the extent possible, while the relatively lower components 16b are likewise grouped together, to the extent possible; in order to minimize the number of zones 20. Based on these layout considerations, at step 102, a frame 18 is created that provides separation between zones 20. At step 104, the frame 18 is then inserted into the enclosure 14 containing the PCB 12, if applicable, or supported on the PCB 12 such that the surface of the PCB 12 is covered and divided into the zones 20 with the peripheral wall 22 in place. The potting material 30 is then injected at step 106, which can be done according to any of the various implementations discussed above. As indicated above, the injection of potting material 30 can be done simultaneously or sequentially, and can be done manually, or automatically by programming a pottant injection machine. In the example shown in FIG. 11, it is determined at step 108, whether or not there are more zones 20 into which potting material 30 should be applied. If so, step 106 is repeated. If not, it is determined at step 110, whether or not the frame 18 is removable. If so, the frame 18 is separated from the PCB 12 at step 112 and the process ends at step 114. It can be appreciated that some or all of the steps shown in FIG. 11 can be implemented as computer executable instructions, executed by software and/or hardware included in, or provided by, the manufacturing equipment.

For simplicity and clarity of illustration, where considered appropriate, reference numerals may be repeated among the figures to indicate corresponding or analogous elements. In addition, numerous specific details are set forth in order to provide a thorough understanding of the examples described herein. However, it will be understood by those of ordinary skill in the art that the examples described herein may be practiced without these specific details. In other instances, well-known methods, procedures and components have not been described in detail so as not to obscure the examples described herein. Also, the description is not to be considered as limiting the scope of the examples described herein.

It will be appreciated that the examples and corresponding diagrams used herein are for illustrative purposes only. Different configurations and terminology can be used without departing from the principles expressed herein. For instance, components and modules can be added, deleted, modified, or arranged with differing connections without departing from these principles.

It will also be appreciated that any module or component exemplified herein that executes instructions may include or otherwise have access to computer readable media such as storage media, computer storage media, or data storage devices (removable and/or non-removable) such as, for example, magnetic disks, optical disks, or tape. Computer storage media may include volatile and non-volatile, removable and non-removable media implemented in any method or technology for storage of information, such as computer readable instructions, data structures, program modules, or other data. Examples of computer storage media include RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by an application, module, or both. Any such computer storage media may be part of any suitable manufacturing equipment performing at least part of the methods described herein, any component of or related thereto, etc., or accessible or connectable thereto. Any application or module herein described may be implemented using computer readable/executable instructions that may be stored or otherwise held by such computer readable media.

The steps or operations in the flow charts and diagrams described herein are just for example. There may be many variations to these steps or operations without departing from the principles discussed above. For instance, the steps may be performed in a differing order, or steps may be added, deleted, or modified.

Although the above principles have been described with reference to certain specific examples, various modifications thereof will be apparent to those skilled in the art as outlined in the appended claims.

1. A frame for applying potting material to a printed circuit board (PCB), the frame comprising a plurality of substantially vertically oriented walls arranged to isolate a surface of the PCB into a plurality of zones.

2. The frame of claim 1, wherein the frame is sized to fit within an enclosure housing the PCB.

3. The frame of claim 1, wherein the frame comprises a peripheral wall to enclose at least one zone near an edge of the PCB.

4. The frame of claim 1, wherein the plurality of zones contain surface-mounted or embedded circuit components of at least two different heights.

5. The frame of claim 1, further comprising a marker in at least one zone to identify a fill line for the potting material.

6. The frame of claim 1, wherein the frame is a unitary piece.

7. The frame of claim 1, wherein the frame is assembled from a plurality of frame pieces.

8. The frame of claim 1, wherein the frame bonds to the potting material.

9. The frame of claim 1, wherein the frame is separable from the potting material after the potting material has been cured.

10. The frame of claim 1, wherein at least one wall of the frame does not extend completely to the PCB to provide a gap between the frame and the PCB.

11. The frame of claim 1, wherein the height of the walls are substantially the same.

12. The frame of claim 1, wherein at least two walls of the frame differ in height.

13. The frame of claim 1, wherein the frame layout is determined when the PCB layout is determined.

14. A method of applying potting material to a printed circuit board (PCB), the method comprising:
aligning a frame over a surface of the PCB, the surface comprising a plurality of components having different heights, the frame comprising a plurality of substantially vertically oriented walls arranged to isolate the surface of the PCB into a plurality of zones, each zone comprising at least one PCB component; and
applying the potting material into a plurality of the zones to achieve coverage of the PCB components in that zone, wherein at least two zones have potting material levels that are different.

15. The method of claim 14, further comprising inserting the frame into an enclosure housing the PCB.

16. The method of claim 14, wherein the frame comprises a peripheral wall to enclose at least one zone near an edge of the PCB.

17. The method of claim 14, wherein the frame comprises a marker in at least one zone to identify a fill line for the potting material.

18. The method of claim 14, wherein the frame is a unitary piece.

19. The method of claim 14, wherein the frame is assembled from a plurality of frame pieces.

20. The method of claim 14, wherein the frame bonds to the potting material.

21. The method of claim 14, wherein the frame is separable from the potting material, the method further comprising separating the frame from the potting material after the potting material has been cured.

22. The method of claim 14, wherein at least one wall of the frame does not extend completely to the PCB to provide a gap between the frame and the PCB.

23. The method of claim 14, wherein the height of the walls are substantially the same.

24. The method of claim 14, wherein at least two walls of the frame differ in height.

25. The method of claim 14, further comprising designing a layout for the frame and a layout for the PCB at the same time to organize PCB components of similar heights to minimize the number of zones.

26. A device for applying potting material to a printed circuit board (PCB), the device comprising a removable frame having a contour that substantially follows contours defined by components of the PCB to enable a gap to be defined between the contour and the PCB components to enable the potting material to be injected into the gap to generate a layer of potting material over the PCB components after removing the frame from the cured potting material.
